(19) United States
(12) Patent Application Publication
(10) Pub. No.: US 2025/0044702 A1
(43) Pub. Date: Feb. 6, 2025

(54) ILLUMINATION OPTICAL UNIT FOR PROJECTION LITHOGRAPHY

(71) Applicant: Carl Zeiss SMT GmbH, Oberkochen (DE)

(72) Inventor: Michael Patra, Oberkochen (DE)

(21) Appl. No.: 18/921,505

(22) Filed: Oct. 21, 2024

Related U.S. Application Data
(63) Continuation of application No. PCT/EP2023/059023, filed on Apr. 5, 2023.

(30) Foreign Application Priority Data
Apr. 27, 2022 (DE) 10 2022 204 098.8

(51) Int. Cl. G03F 7/00

(52) U.S. Cl. CPC G03F 7/70075; G03F 7/70033; G03F 7/7015; G03F 7/702; G03F 7/70233

(57) ABSTRACT

An illumination optical unit for projection lithography illuminates an object field of a downstream imaging optical unit with illumination light from an EUV light source. A first facet mirror has a plurality of adjacently arranged first facets for specifying partial fields which are transferred into partial sections of the object field using the illumination optical unit. A further facet mirror disposed downstream of the first facet mirror has a plurality of adjacently arranged, individually tiltable further facets. The two facet mirrors serve for reflective, at least partially overlaid guidance of component beams of an overall beam of the illumination light via at least one of the first facets and via at least one of the further facets. A curved transfer mirror is disposed downstream of the further facet mirror and serves for the beam-shaping transfer of the overall beam of the illumination light into the object field.

### CROSS-REFERENCE TO RELATED APPLICATIONS

The present application is a continuation of, and claims benefit under 35 USC 120 to, international application No. PCT/EP2023/059023, filed Apr. 5, 2023, which claims benefit under 35 USC 119 of German Application No. 10 2022 204 098.8, filed Apr. 27, 2022. The entire disclosure of each of these applications is incorporated by reference herein.

### FIELD

The disclosure relates to an illumination optical unit for projection lithography. Further, the disclosure relates to an optical system comprising such an illumination optical unit, an illumination system comprising such an illumination optical unit, a projection exposure apparatus comprising such an optical system, a method for producing a microstructured or nanostructured component, and a component produced by the method.

### BACKGROUND

An illumination optical unit for projection lithography is known from, for example, US 2011/0318696 A1, DE 10 2008 001 511 A1, U.S. Pat. No. 9,977,335, WO 2009/100 856 A1 and WO 2008/011 981 A1. DE 103 17 667 A1 discloses an optical element for an illumination system.

### SUMMARY

The disclosure seeks to provide an illumination optical unit in which installation space conflicts with a downstream projection optical unit that images the object field are reduced, with high demands with regards to an illumination quality being met at the same time.

In an aspect, the disclosure provides an illumination optical unit for projection lithography for illuminating an object field of a downstream imaging optical unit, in which an object to be illuminated is arrangeable, with illumination light from an EUV light source.

The illumination optical unit has a first facet mirror with a plurality of adjacently arranged first facets for specifying partial fields which are transferred into partial sections of the object field using the illumination optical unit. The illumination optical unit has a further facet mirror which is disposed downstream of the first facet mirror in a beam path of the illumination light and which has a plurality of adjacently arranged, individually tiltable further facets. The two facet mirrors are designed for reflective, at least partially overlaid guidance of component beams of an overall beam of the illumination light via at least one of the first facets and via at least one of the further facets. The illumination also has a curved transfer mirror which is disposed downstream of the further facet mirror and serves to transfer the overall beam of the illumination light into the object field. The object field is arcuate. The illumination optical unit has an assignment of the first facets to the second facets for respective guidance of one of the illumination light component beams, in such a way that there is compensation of a pupil-varying effect of an imaging variation which is caused by the transfer mirror during the transfer of the partial fields into the object field which is the result during the transfer of the rectangular partial fields into the arcuate object field.

An insight the disclosure involves was that a curved transfer mirror disposed downstream of the further facet mirror can be desirable in the case of an illumination optical unit in which partial fields are transferred into partial sections of the object field. The additional curved, i.e. non-planar, transfer mirror for example allows field shaping of the object field, and this can be used for the shaping of upstream components in the illumination light beam path. Moreover, a folding effect of the transfer mirror reduces the risk of installation space conflicts. The curved design of the transfer mirror yields a transfer mirror with a refractive power effect and an effect on the shape of a beam of the illumination light incident on the transfer mirror; this is also referred to as a beam-shaping effect below. These partial fields can be imaged into partial sections of the object field when the partial fields are transferred into the partial sections of the object field. An enlarging or size-reducing imaging effect of the transfer mirror may represent an additional degree of freedom when designing optical components of the illumination optical unit; for example, this can be used to reduce and/or adapt the size of such optical components. In the case of such imaging, the first facet mirror is arranged in a field plane of the illumination optical unit. Alternatively, the first facet mirror can also be arranged at a distance from such a field plane. The guidance of the respective component beam can be implemented via exactly one of the first facets and/or via exactly one of the further facets.

In embodiments, the partial sections of the object field into which the partial fields specified by the first facets are transferred make up an area of the entire object field which can be no more than 50%. This area can be smaller and can be no more than 45%, no more than 40%, no more than 35%, no more than 33.3%, no more than 30%, no more than 25%, no more than 20% of the entire area of the object field. An even smaller area is also possible, for example 10% or 5%. This area is regularly more than 1%.

The use of individually tiltable further facets on the further facet mirror can allow greater freedom in the selection and shaping of the component beams.

The object field is arcuate. Such a design of the illumination optical unit can allow a good imaging aberration correction of a downstream projection optical unit for imaging the object field.

The first facets are assigned to the second facets for respective guidance of one of the illumination light component beams, in such a way that there is compensation of a pupil-varying effect of an imaging variation which is caused by the transfer mirror during the transfer of the partial fields into the object field which is the result during the transfer of the rectangular partial fields into the arcuate object field. Such a facet assignment can take account of the fact that a transfer of rectangular partial fields into an arcuate object field regularly leads to an imaging variation which has a pupil-varying effect on an illumination pupil of the illumination optical unit. The compensation of the pupil-varying effect of the imaging variation which is caused by the transfer mirror during the transfer of the partial fields into the object field, which is the result during the transfer of the rectangular partial fields into the arcuate object field, on account of the facet assignment is also referred to as imaging-compensatory effect.

Without the assignment compensation, the illumination light component beams could be guided toward the partial sections of the object field with different illumination angle distributions, and so an unwanted pupil variation can arise. The assignment results in a compensation of unwanted effects of such an imaging variation. For example, an illumination angle distribution which is field-independent to a good approximation can then be obtained for the object illumination. The facet assignment can arise by way of an appropriate distribution of tilts of the first facets, with the result that the component beams of the illumination light incident on the first facets can be guided toward the assigned second facets.

In some embodiments, the further facet mirror is arranged at a distance from an entrance pupil plane of a downstream imaging optical unit. In such embodiments, with a first facet mirror for partial field specification and a downstream second facet mirror, spaced apart from an illumination optical unit pupil plane, is also known as a specular reflector in the prior art. Such a specular reflector regularly assumes that an object field illumination is formed from partial sections and that individually tiltable further facets are available on a further facet mirror.

In some embodiments, the transfer mirror is a grazing incidence (GI) mirror. Such embodiments can allow illumination light to be guided with small reflection losses. An angle of incidence of the illumination light on the GI mirror can be greater than 45°. This angle of incidence can be greater than 60°, can be greater than 65°, and can also be greater than 70°. This angle of incidence is regularly less than 89°.

In some embodiments, the first facets have a rectangular reflection surface edge, with the result that the partial fields specified by way of the first facets are rectangular. Such a rectangular reflection surface edge for the first facets can allows tight packing of the first facets on the first facet mirror in at least one packing dimension, optionally in the two packing dimensions that span an arrangement plane of the first facet mirror.

The object field can have a partial-ring-shaped configuration.

The beam-shaping effect of the transfer mirror can be formed in such a way that rectangular partial fields specified by the first facets are transferred into the actuate or partial-ring-shaped object field in partial sections with a correspondingly arcuate design.

In some embodiments, the partial sections has an extent transverse to an object displacement direction which is no more than 50% of an object field extent of the object field transverse (x) to the object displacement direction. Such a transverse extent of the partial sections has proven its worth in practice. This extent of the partial sections transverse to the object displacement direction can be no more than 40% of the entire object field extent transverse to the object displacement direction, can make up no more than 30%, no more than 25%, no more than 20% or else no more than 5%, and optionally it can also be even less. This transverse extent of the partial sections is regularly greater than 1% of the transverse extent of the entire object field.

In some embodiments, the first facets are subdivided into a plurality of adjacently arranged individual mirrors, which are able to be grouped and/or able to be tilted on an individual basis. Such a subdivision of the first facets can help enable much flexibility when using the illumination optical unit. A group specified by way of the individual mirrors, for example, can then yield one of the first facets. The individual mirror groups can have a rectangular edge, and can in that case specify partial fields with a rectangular edge in turn.

In some embodiments, at least some of the partial sections have an extent over the entire object field along an object displacement direction. Such an extent of the partial fields along the object displacement direction has proven its worth in practice. Alternatively, the partial fields may also be subdivided along the object displacement direction, with the result that, along the object displacement direction as well, the partial sections have an extent smaller than the overall extent of the object field in the object displacement direction.

Features of a corresponding optical system, a corresponding illumination system, a corresponding projection exposure apparatus, a corresponding production method, and a correspondingly produced microstructured or nanostructured component can correspond to those which have already been explained above with reference to the illumination optical unit. The component produced may be a semiconductor element, especially a microchip, for example a memory chip.

At least one exemplary embodiment of the disclosure is described hereinafter with reference to the drawing.

### BRIEF DESCRIPTION OF THE DRAWINGS

In the drawings:

FIG. 1 schematically shows a meridional section of a projection exposure apparatus for EUV projection lithography;

FIG. 2 schematically shows a transmission of partial fields, which are specified by adjacently arranged first facets of a first facet mirror of the illumination optical unit, into partial sections of an object field of a downstream imaging optical unit of the projection exposure apparatus, the transmission being implemented using an illumination optical unit of the projection exposure apparatus according to FIG. 1 via a transmission optical unit comprising a further facet mirror and a transfer mirror;

FIG. 3 shows an illustration similar to FIG. 2 in principle but less abstract in relation to the transmission optical unit, the transfer of three partial fields depicted in FIG. 3 into the object field, wherein, in relation to the guidance of component beams of an illumination light overall beam assigned to the partial fields, a respective distribution of the illumination light on illuminated sub-pupils within an illumination pupil of the illumination optical unit and a transfer mirror disposed downstream of the illumination pupil and serving to transfer the entire illumination light beam into the object field are also illustrated;

FIG. 4 schematically shows the guidance of an illumination light component beam from an intermediate focus between firstly a collector of the projection exposure apparatus and the illumination optical unit and secondly the object field, for the purpose of illustrating typical dimensions for designing components of the illumination optical unit; and

FIGS. 5 and 6 show, in portions, exemplary occupancies of sections of the first facet mirror with the first facets for specifying the partial fields.

### DETAILED DESCRIPTION

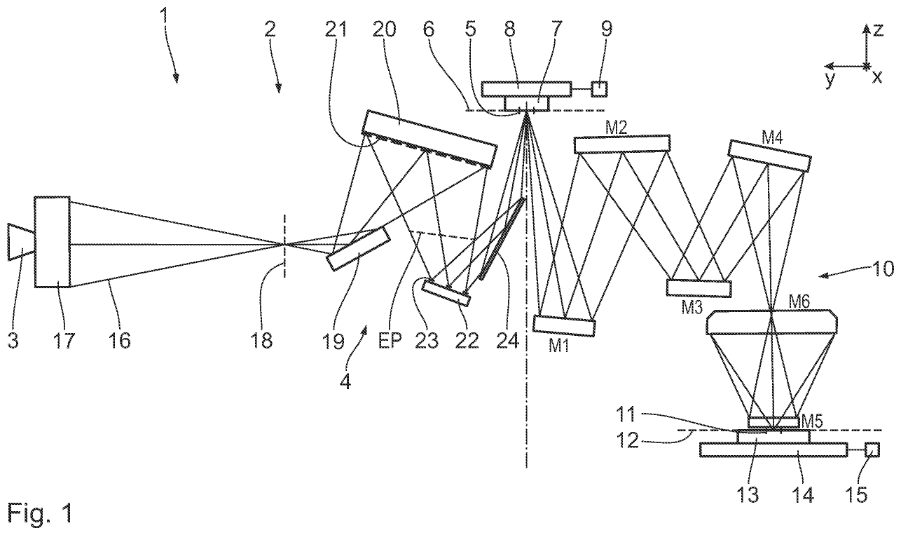

Certain components of a microlithographic projection exposure apparatus 1 are first described by way of example hereinafter with reference to FIG. 1. The description of the basic setup of the projection exposure apparatus 1 and its components should not be regarded as limiting here.

One design of an illumination system 2 of the projection exposure apparatus 1 has, in addition to a light or radiation source 3, an illumination optical unit 4 for illuminating an object field 5 in an object plane 6. In an alternative design, the light source 3 may also be provided as a module separate from the rest of the illumination system. In this case, the illumination system does not comprise the light source 3.

The object field 5 is arcuate. The object field 5 can have a partial-ring-shaped design.

A reticle 7 arranged in the object field 5 is exposed. The reticle 7 is held by a reticle holder 8. The reticle holder 8 is displaceable, for example in a scanning direction, by way of a reticle displacement drive 9.

FIG. 1 shows a Cartesian xyz-coordinate system for explanatory purposes. The x-direction runs perpendicular to the plane of the drawing. The y-direction runs horizontally, and the z-direction runs vertically. The scanning direction runs along the y-direction in FIG. 1. The z-direction runs perpendicular to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. As an alternative, an angle that differs from 0° between the object plane 6 and the image plane 12 is also possible.

A structure on the reticle 7 is imaged on a light-sensitive layer of a wafer 13 arranged in the region of the image field 11 in the image plane 12. The wafer 13 is held by a wafer holder 14. The wafer holder 14 is displaceable by way of a wafer displacement drive 15, for example along the y-direction. The displacement, firstly, of the reticle 7 by way of the reticle displacement drive 9 and, secondly, of the wafer 13 by way of the wafer displacement drive 15 can be synchronized with one another.

The radiation source 3 is an EUV radiation source. The radiation source 3 emits, for example, EUV radiation 16, which is also referred to below as used radiation, illumination radiation, or illumination light or imaging light. For example, the used radiation has a wavelength in the range of between 5 nm and 30 nm. The radiation source 3 can be a plasma source, for example an LPP (laser produced plasma) source or a GDPP (gas discharge produced plasma) source. It can also be a synchrotron-based radiation source. The radiation source 3 can be a free electron laser (FEL).

The illumination radiation 16 emerging from the radiation source 3 is focused by a collector 17. The collector 17 may be a collector with one or more ellipsoidal and/or hyperboloid reflection surfaces. The illumination radiation 16 can be incident on the at least one reflection surface of the collector 17 with grazing incidence (GI), i.e. at angles of incidence of greater than 45°, or with normal incidence (NI), i.e. at angles of incidence of less than 45°. The collector 17 may be structured and/or coated, both to optimize its reflectivity for the used radiation and to suppress extraneous light. Together with the light source 3, the collector 17 can form a source-collector module.

Downstream of the collector 17, the illumination radiation 16 propagates through an intermediate focus in an intermediate focal plane 18. The intermediate focal plane 18 can represent a separation between a radiation source module, comprising the radiation source 3 and the collector 17, and the illumination optical unit 4.

The illumination optical unit 4 comprises a deflection mirror 19 and, arranged downstream thereof in the beam path, a first facet mirror 20. The deflection mirror 19 may be a plane deflection mirror or, alternatively, a mirror with a beam-influencing effect going beyond the pure deflection effect. In an alternative to that or in addition, the deflection mirror 19 can be designed as a spectral filter that separates a used light wavelength of the illumination radiation 16 from extraneous light at a different wavelength. If the first facet mirror 20 is arranged in a plane of the illumination optical unit 4 that is optically conjugate to the object plane 6 as a field plane, it is also referred to as a field facet mirror. The first facet mirror 20 comprises a plurality of individual first facets 21, which are also referred to below as field facets. FIG. 1 illustrates only some of the facets 21 by way of example.

The first facet mirror 20 is located in a far field of the illumination light 16. The far field can be located approximately in a Fourier-conjugate plane to the light or radiation source 3.

The first facets 21 may be designed as macroscopic facets, for example as rectangular facets or as facets with an arcuate edge contour or an edge contour of part of a circle. The first facets 21 can be designed as plane facets or alternatively as facets with convex or concave curvature. The first facets 21 are tiltable on an individual basis with the aid of assigned actuators.

As is known for example from DE 10 2008 009 600 A1, the first facets 21 themselves can also each be composed of a multiplicity of individual mirrors, for example a multiplicity of micromirrors. The first facet mirror 20 may for example take the form of a microelectromechanical system (MEMS system). For details, reference is made to DE 10 2008 009 600 A1.

The illumination radiation 16 travels horizontally, i.e., along the y-direction, between the collector 17 and the deflection mirror 19.

In the beam path of the illumination optical unit 4, a second or further facet mirror 22 is disposed downstream of the first facet mirror 20. The second facet mirror 22 is located at a distance from an entrance pupil plane EP of the downstream projection optical unit 10, the entrance pupil plane being illustrated by way of example between the two facet mirrors 20, 22 in FIG. 1. The entrance pupil EP is the entrance-side image of the aperture-restricting stop of the projection optical unit 10.

In the beam path of the illumination light 16, the entrance pupil plane EP of the projection optical unit 10 can be arranged upstream or downstream of the second facet mirror 22. A spacing of the entrance pupil plane from an arrangement plane of the second facet mirror 22 is at least 5% of a spacing between the two facet mirrors 20, 22.

The combination of the first facet mirror 20 and the second facet mirror 22 is also referred to as a specular reflector. In principle, specular reflectors are known from U.S. Pat. No. 9,977,335 or US 2006/0132747 A1, EP 1 614 008 B1 and U.S. Pat. No. 6,573,978.

The second facet mirror 22 comprises a plurality of second facets 23, which are also referred to as specular facets. The illumination optical unit 4 thus forms a double-faceted system.

The second facets 23 can likewise be macroscopic facets, which can for example have a round, rectangular or else hexagonal edge, or can alternatively be facets composed of micromirrors. In this regard, reference is likewise made to DE 10 2008 009 600 A1.

The second facets 23 can have plane reflection surfaces or, alternatively, convexly or concavely curved reflection surfaces. The second facets 23 are tiltable on an individual basis with the aid of assigned actuators.

A transfer mirror 24 contributing to imaging the first facets 21 into the object field 5 is arranged in the beam path between the second facet mirror 22 and the object field 5. The transfer mirror 24 is designed as a grazing incidence mirror (GI mirror). A smallest angle of incidence of the illumination light 16 on the transfer mirror 24 is greater than 45°, and can be greater than 60°, can be greater than 65°, can be greater than 70°, can be greater than 75° and can also be even greater.

In the embodiment shown in FIG. 1, the illumination optical unit 4 comprises exactly four mirrors downstream of the collector 17, specifically the deflection mirror 19, the field facet mirror 20, the further facet mirror 22 and the transfer mirror 24. Depending on the design of the illumination optical unit 4, the deflection mirror 19 can also be omitted, with the result that the first facet mirror 20 is the first beam-guiding component for the illumination light 16 downstream of the intermediate focal plane 18. A reflection surface of the transfer mirror 24 deviates from a plane surface, i.e. it does not run in a planar manner but rather in a curved manner.

The transfer mirror 24 has a beam-shaping effect on the overall beam of the illumination light 16. Depending on its design, the transfer mirror 24 has an imaging effect with an imaging factor that has a magnifying or, alternatively, size-reducing effect. An imaging factor of less than 1 describes a size-reducing imaging factor below. An imaging factor of greater than 1 describes a magnifying imaging factor.

In yet another alternative, the imaging factor can be 1, or the transfer mirror 24 can bring about imaging with imaging factors that differ firstly in the x-direction and secondly in the y-direction. The imaging factor of the transfer mirror 24 can have a value ranging between 0.1 and 10 in the x-direction and/or in the y-direction. For example, the imaging factor can lie in the range between 0.125 and 8, can be between 0.25 and 4, can be between 0.33 and 3, can be between 0.5 and 2, and can also be between 0.75 and 1.25 or else between 0.9 and 1.1.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mi are likewise possible. The projection optical unit 10 is a doubly obscured optical unit. The penultimate mirror M5 and the last mirror M6 each have a passage opening for the illumination radiation 16. The projection optical unit 10 has an image-side numerical aperture that is greater than 0.5 and can also be greater than 0.6 and can be for example 0.7 or 0.75.

Reflection surfaces of the mirrors Mi can be in the form of free-form surfaces without an axis of rotational symmetry. Alternatively, the reflection surfaces of the mirrors Mi can be in the form of aspherical surfaces with exactly one axis of rotational symmetry of the reflection surface shape. Just like the mirrors of the illumination optical unit 4, the mirrors Mi may comprise highly reflective coatings for the illumination radiation 16. These coatings may be in the form of multi-layer coatings, for example with alternating layers of molybdenum and silicon.

The projection optical unit 10 has a large object-image offset in the y-direction between a y-coordinate of a center of the object field 5 and a y-coordinate of the center of the image field 11. In the y-direction, this object-image offset can be of approximately the same size as a z-distance between the object plane 6 and the image plane 12.

The projection optical unit 10 may for example have an anamorphic form. For example, it has different imaging scales βₓ, β_{y} in x- and y-directions. The two imaging scales βₓ, β_{y} of the projection optical unit 10 can be at (βₓ, β_{y})=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction, i.e. in a direction perpendicular to the scanning direction.

The projection optical unit 10 leads to a reduction in size of 8:1 in the y-direction, i.e. in the scanning direction.

Other imaging scales are likewise possible. Imaging scales with the same signs and the same absolute values in the x-direction and y-direction, for example with absolute values of 0.125 or 0.25, are also possible.

The number of intermediate image planes in the x-direction and in the y-direction in the beam path between the object field 5 and the image field 11 may be the same or may be different depending on the design of the projection optical unit 10. Examples of projection optical units with different numbers of such intermediate images in the x and y directions are known from US 2018/0074303 A1.

The first facets 21 of the first facet mirror 20 serve to specify partial fields which are transferred into partial sections 25; of the object field 5 using the illumination optical unit 4. This transfer can be imaging. The respective second facet 23, which may in turn comprise a plurality of small individual mirrors and which is used on the second facet mirror 22 to guide a respective component beam 16ᵢ, is also referred to as virtual partial field facet 23 hereinbelow.

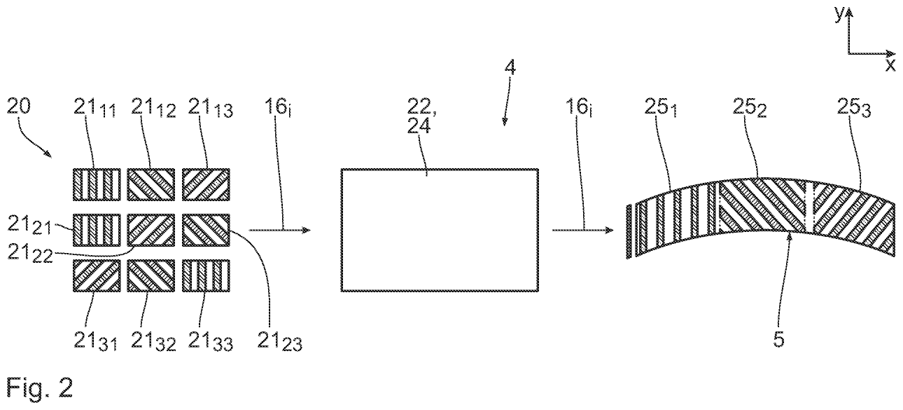

FIG. 2 clarifies this transfer by the first facets 21 into the partial sections 25 of the object field 5 on the basis of a total of nine first facets 21ᵢⱼ, which are arranged in three rows (i=1, 2, 3) and in three columns (j=1, 2, 3). Accordingly, FIG. 2 depicts a section of the first facet mirror 20 with a total of nine first facets 21ᵢⱼ. In fact, the number of first facets 21 of the first facet mirror 20 is significantly larger and can be in the range of several 100, for example.

Each first facet 21 can consist of a contiguous macroscopic reflection surface. Alternatively, each first facet 21 can consist of a plurality of adjacent micromirrors.

Component beams 16ᵢ of an overall beam of the illumination light 16 are reflected in each case by the first facets 21ᵢⱼ, and the partial fields specified by the first facets 21ᵢⱼ are thus transferred into the partial sections 25₁, 25₂, 25₃ of the object field 5. The transfer optical unit serving for this end, which is formed by the second facet mirror 22 and the transfer mirror 24, is only depicted schematically in FIG. 2.

The first facets 21ᵢⱼ are designed with a rectangular reflection surface edge such that the partial fields specified by way of the first facets 21ᵢⱼ are rectangular.

By way of component beams 16i, which are reflected by the first facets 21₁₁, 21₂₁ and 21₃₃, are transferred in overlaid fashion into the partial section 25₁ depicted to the left of the object field 5 in FIG. 2 by the transmission optical unit 22, 24. Component beams 16ᵢ, which are reflected by the first facets 21₁₂, 21₂₃ and 21₃₂, are transferred into the partial section 25₂ depicted in the center of the object field 5 in FIG. 2 by means of the transmission optical unit 22, 24. Component beams 16ᵢ, which are reflected by the first facets 21₁₃, 21₂₂ and 21₃₁, are transferred into the partial section 25₃ depicted to the right of the object field 5 in FIG. 2 by means of the transfer optical unit 22, 24.

Transverse to the object displacement direction y, i.e. along the x direction, the partial sections 25ᵢ have an extent amounting to a third of an x-extent of the object field. Depending on the design of the illumination optical unit 4, this x-extent of the partial sections can be no more than 50%, can be no more than 40%, can be no more than 30%, can be no more than 25%, can be no more than 10%, and can for example be 5% or optionally be even smaller. This x-extent of the partial sections 25 is regularly greater than 1% of the x-extent of the object field 5.

The partial sections 25 have an extent over the entire object field 5 along the object displacement direction y. Alternatively, it is possible that a plurality of adjacent partial fields are also present along the y-direction, for example two, three or even more such partial fields.

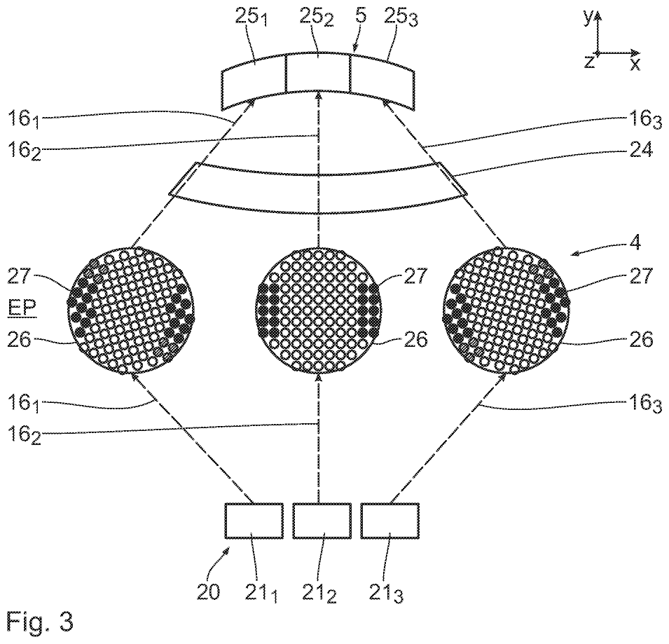

FIG. 3 illustrates an imaging-compensatory effect of a facet assignment of the facets 21, 23 of the two facet mirrors 20, 22 to the respective component beams 16ᵢ. In contrast to FIG. 2, FIG. 3 depicts the beam paths of three component beams emanating from exactly three first facets 21₁, 21₂ and 21₃ by way of example.

FIG. 3 illustrates the effect of the second facet mirror 22 and of the transfer mirror 24 on the basis of the illumination pupil 26 which is depicted for each component beam 16₁, 16₂, 16₃ and has sub-pupils 27 that are plotted in filled fashion and illuminated in the case of the respective guidance of the component beams 16₁, 16₂, 16₃. Each of the component beams 16ᵢ is guided via exactly one second facet 23 and is associated with exactly one of the sub-pupils 27.

For illustrative purposes, the illumination pupils 26 for guiding the three component beams 16₁ to 16₃ are depicted separately in FIG. 3. In fact, this relates to one and the same illumination pupil 26; however, on account of the pupil-rotating imaging effect of the transfer mirror 24, the illumination pupil is continuously twisted with the location of incidence on the object field 5 through a different rotary angle about an axis parallel to the z-axis. Accordingly, the poses of the sub-apertures 27 are twisted relative to one another in the various depicted illumination pupils 26. The rotary angle depends continuously on the location of incidence, and so there is a rotation even within a partial section or partial field 25ᵢ of a component beam. The depicted illumination pupils 26 relate to a location within the corresponding partial field 25ᵢ.

The transfer of a component beam 16ᵢ of one of the first facets 21 by means of the non-planar transfer mirror 24, i.e. by means of the transfer mirror with refractive power, leads to a change in shape of the illumination in the plane of the object field 5, i.e. the shape of the partial section 25ᵢ differs from the shape of the corresponding first facet 21ᵢ. For example, the partial section 25ᵢ becomes curved, or its curvature changes.

Illumination radiation 16 of one or more component beams 16ᵢ, which is guided via the same second facet 23, leads to the illuminated sub-pupil 27 within the entrance pupil 26.

The entrance pupil 26 is located in the entrance pupil plane EP. The use of the non-planar transfer mirror 24 leads to the location of the sub-pupil 27 within the entrance pupil 26 becoming field-dependent, i.e. depending on the location of incidence of the illumination radiation 16 in the object field 5. For example, there is a twist about an axis parallel to the z-axis, wherein the angle of rotation depends approximately linearly on the x-position.

Together with the second facet mirror 22 not depicted in FIG. 3, the transfer mirror 24 ensures a transfer of the rectangular partial fields, which are specified by the first facets 21ᵢⱼ, into the partial sections 25ᵢ that are suitably bent for the respective x-position on the object field 5.

The imaging effect of the transfer mirror 24 for transmitting the rectangular partial fields, which are specified by way of the first facets 21ᵢ, into the bent partial sections 25ᵢ in the bent object field 5 leads to a twist of a fill of the illumination pupil 26 in the pupil plane EP if the component beams 16ᵢ were to be incident on the same facets 23 of the second facet mirror 22.

This twist of the illumination pupil fill is compensated by an actually occurring, individual assignment of the second facets 23 of the second facet mirror 22 to the various component beams 16ᵢ:

FIG. 3 elucidates, in the center, the guidance of the component beam 16₂ from the partial field specified by the first facet 21₂ to the partial section 25₂ via illuminated sub-pupils 27, depicted as filled in the center of FIG. 3, and via a subsequent reflection at the transfer mirror 24.

To the left, FIG. 3 shows the guidance of the component beam 16₁ from the first facet 21₁ to the partial section 25₁ on the object field 5. On account of the twist of the illumination pupil fill, those sub-pupils 27 illuminated during the guidance of the component beam 16₂ now appear twisted when guiding the component beam 16₁. In order to obtain an illumination pupil fill corresponding to that of the guidance of the component beam 16₂ when guiding the component beam 16₁, twisted groups of the sub-pupils 27 are illuminated when guiding the component beam 16₁ in comparison with the guidance of the component beam 16₂, and this in turn is elucidated by filled sub-pupils 27. Those sub-pupils 27 impinged during the guidance of the component beam 16₂ but not impinged during the guidance of the component beam 16₁ are depicted with hatching on the illumination pupil 26 to the left in FIG. 3.

As a result, despite the pupil-twisting imaging effect of the transfer mirror 24, the partial section 25₁ of the object field 5 specified by the first facet 21₁ sees, to a good approximation, the same distribution of illumination angles specified by the sub-pupils 27 as the partial section 25₂.

Accordingly, there is an assignment of the sub-pupils 27 impinged by the illumination light of the component beam 16₃; this is depicted to the right in FIG. 3. Once again, the illuminated facets are depicted in filled fashion, and those sub-pupils 27 that are not impinged during the guidance of the component beam 16₃ but are impinged during the guidance of the component beam 16₂ are depicted with hatching. As a result, the partial section 25₃, in which the component beam 16₃ starting from the partial field specified by the first facet 21₃, sees an illumination angle distribution corresponding to that of the partial fields 25₂ and 25₁.

Hence, to a good approximation, the same illumination angle distribution arises over the entire object field 5 despite the pupil-rotating imaging effect of the transfer mirror 24. A rotation within an individual partial field 25ᵢ remains as pupil-rotating residual imaging effect of the transfer mirror 24. The strength of this residual effect can be limited by choosing the size of the partial fields 25ᵢ in a manner corresponding to a choice of the size of the first facets 21ᵢ.

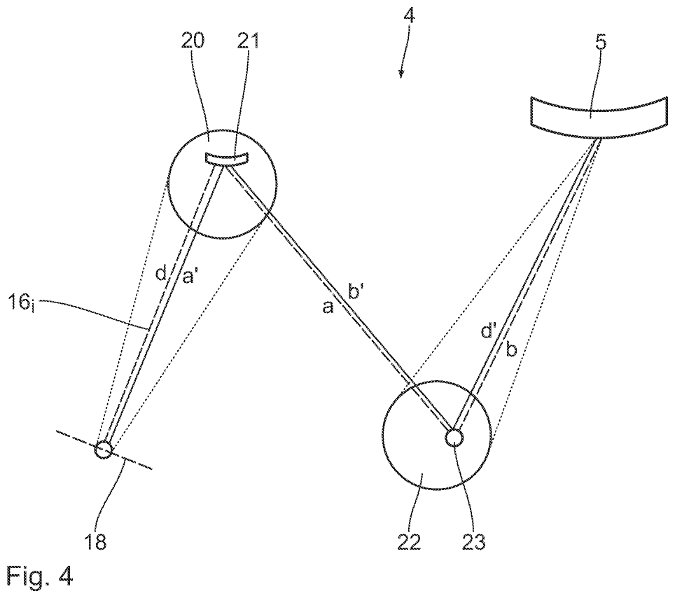

FIG. 4 illustrates typical dimensions when designing the illumination optical unit 4. The light path of a component beam 16ᵢ is shown between the intermediate focus in the intermediate focal plane 18 and the object field 5 via one of the first facets 21 and one of the second facets 23. The transfer mirror 24 has been omitted from FIG. 4.

The size of the individual first facet 21 arises from the size of the object field 5 multiplied by a factor a/b, where a is the light path between the first facet 21 and the second facet 23, and b is the light path between the second facet 23 and the respective partial section 25ᵢ on the object field 5.

The size of the respective virtual partial facet 23 arises from a typical diameter of the intermediate focus in the intermediate focal plane 18, multiplied by a factor b′/a′. Here, a′ is the light path of the component beam 16ᵢ between the intermediate focus and the first facet 21. b′ is the light path between the first facet 21 and the virtual partial field facet 23.

The size of the entire first facet mirror 20 arises from a numerical aperture of the overall beam of the illumination light 16 at the intermediate focus 18 and the distance d between the intermediate focus and the first facet mirror 20. To a good approximation, the following applies here: d≅a′.

The size of the entire second facet mirror 22 arises from the numerical aperture of the overall beam of the illumination light 16 at the object field 5 and the light path d′ between the second facet mirror 22 and the object field 5. The following applies to a good approximation: b≅d′.

A number of the field facets 21 arises from the size of the latter and the size of the field facet mirror 20. A number of the virtual partial field facets 23 arises from the size of the latter and the size of the second facet mirror 22.

In the absence of a transfer mirror 24 with refractive power, the relevant parameters of the components of the illumination optical unit, for example the size of the facet mirror 20, 22 or the size and number of the partial field facets 23, emerge directly from the geometry of the illumination optical unit 4, i.e. the spacings between the components within the illumination optical unit. Therefore, these parameters thus cannot be chosen freely, in order for example to reduce production costs. The use of a transfer mirror 24 with refractive power leads to a degree of freedom for adjusting these parameters; for example, this can be used to reduce production costs.

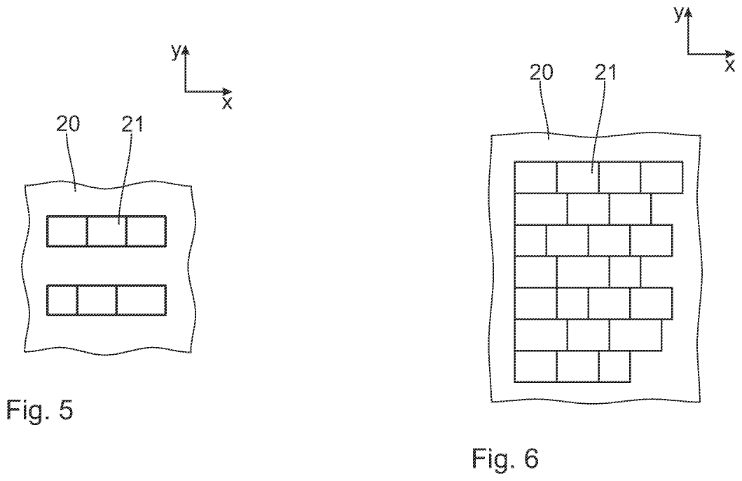

By way of example, FIGS. 5 and 6 show typical configurations of the first facets 21 on the first facet mirror 20. This configuration can be tightly packed in rows, i.e. along the x-direction (FIG. 5).

Additionally, the first facets 21 can also be configured with tight packing in the y-direction, as depicted in FIG. 6. The rectangular edge of the first facets 21 and their edge orientations in each case parallel to the x-direction and also the y-direction allow such tight packing.

The illumination of the object field 5 is for example as homogeneous as possible. It can have a uniformity error of less than 2%. The field uniformity can be attained by overlaying different illumination channels or component beams 16ᵢ.

The illumination of the entrance pupil of the projection optical unit 10 can be defined geometrically by an arrangement of the second facets 23. The intensity distribution in the entrance pupil of the projection optical unit 10 can be set by selecting the illumination channels or component beams 16ᵢ, for example the subset of the sub-pupils 27 which guide light and are assigned thereto in each case. This intensity distribution is also referred to as illumination setting or illumination pupil filling.

A likewise preferred pupil uniformity in the region of sections of an illumination pupil of the illumination optical unit 4 which are illuminated in defined fashion can be attained by a redistribution of the illumination channels or component beams 16ᵢ and by a redistribution of the virtual partial field facets 23 for guiding a respective one of the component beams 16ᵢ.

Further aspects and details of the illumination of the object field 5 and for example of the entrance pupil of the projection optical unit 10 are described hereinafter.

The projection optical unit 10 may have a homocentric entrance pupil for example. The latter can be accessible. It can also be inaccessible.

It may be the case that the projection optical unit 10 has different poses of the entrance pupil for the tangential beam path and for the sagittal beam path. In this case, an imaging element, for example an optical component of the transmission optical unit, should be provided between the second facet mirror 22 and the reticle 7. The different position of the tangential entrance pupil and the sagittal entrance pupil are able to be taken into account using this optical element. This imaging element of the transmission optical unit can be identical to the transfer mirror 24.

In order to produce a microstructured component, for example a highly integrated semi-conductor component, for example a memory chip, with the aid of the projection exposure apparatus 1, firstly the reticle 7 and the wafer 13 are provided. Afterwards, a structure on the reticle 7 is projected onto a light-sensitive layer on the wafer 13 by means of the projection optical unit of the projection exposure apparatus 1. By developing the light-sensitive layer, a microstructure is then generated on the wafer 13 and the micro-structured or nanostructured component is produced herefrom.

What is claimed is:

1. An illumination optical unit configured to illuminate an object field of a down-stream projection optical unit with illumination light, the illumination optical unit comprising:
a first facet mirror comprising plurality of adjacent first facets configured to specify partial fields transferrable into partial sections of the object field via the illumination optical unit;
a second facet mirror downstream of the first facet mirror along a beam path of the illumination light, the second fact mirror comprising a plurality of adjacent, individually tiltable second facets, the first and second facet mirrors configured for reflective, at least partially overlaid guidance of component beams of an overall beam of the illumination light via at least one of the first facets and via at least one of the further facets;
a curved transfer mirror downstream of the second facet mirror along the beam path, the curved transfer mirror configured to transfer the overall beam of the illumination light into the object field,
wherein:
the object field is arcuate;
the first facets are assigned to the second facets for respective guidance of one of the illumination light component beams to compensate a pupil-varying effect of an imaging variation caused by the transfer mirror during transfer of the partial fields into the object field resulting from transfer of the rectangular partial fields into the arcuate object field.

2. The illumination optical unit of claim 1, wherein the second facet mirror is a distance from an entrance pupil plane of the downstream imaging optical unit.

3. The illumination optical unit of claim 1, wherein the transfer mirror comprises a grazing incidence mirror.

4. The illumination optical unit of claim 1, wherein the first facets have a rectangular reflection surface edge so that the partial fields specified by way of the first facets are rectangular.

5. The illumination optical unit of claim 1, wherein the object field comprises a partial-ring-shaped configuration.

6. The illumination optical unit of claim 1, wherein the transfer mirror has a beam-shaping effect so that rectangular partial fields specified by the first facets are transferrable into the object field in partial sections with a correspondingly arcuate design.

7. The illumination optical unit of claim 1, wherein the partial sections have an extent in a direction transverse to an object displacement direction that is most 50% of an extent of the object field in the direction transverse to object displacement direction.

8. The illumination optical unit of claim 1, wherein the first facets are subdivided into a plurality of adjacent individual mirrors, which are groupable and/or tiltable on an individual basis.

9. The illumination optical unit of claim 1, wherein at least some of the partial sections have an extent over the entire object field along an object displacement direction.

10. The illumination optical unit of claim 1, wherein the second facet mirror is a distance from an entrance pupil plane of the downstream imaging optical unit, and the transfer mirror comprises a grazing incidence mirror.

11. The illumination optical unit of claim 1, wherein the second facet mirror is a distance from an entrance pupil plane of the downstream imaging optical unit, and the first facets have a rectangular reflection surface edge so that the partial fields specified by way of the first facets are rectangular.

12. The illumination optical unit of claim 1, wherein the second facet mirror is a distance from an entrance pupil plane of the downstream imaging optical unit, and the object field comprises a partial-ring-shaped configuration.

13. The illumination optical unit of claim 1, wherein the second facet mirror is a distance from an entrance pupil plane of the downstream imaging optical unit, and the transfer mirror has a beam-shaping effect so that rectangular partial fields specified by the first facets are transferrable into the object field in partial sections with a correspondingly arcuate design.

14. The illumination optical unit of claim 1, wherein the second facet mirror is a distance from an entrance pupil plane of the downstream imaging optical unit, and the partial sections have an extent in a direction transverse to an object displacement direction that is most 50% of an extent of the object field in the direction transverse to object displacement direction.

15. The illumination optical unit of claim 1, wherein the second facet mirror is a distance from an entrance pupil plane of the downstream imaging optical unit, and the first facets are subdivided into a plurality of adjacent individual mirrors, which are groupable and/or tiltable on an individual basis.

16. The illumination optical unit of claim 1, wherein:
the second facet mirror is a distance from an entrance pupil plane of the down-stream imaging optical unit;
the transfer mirror comprises a grazing incidence mirror; and
the first facets have a rectangular reflection surface edge so that the partial fields specified by way of the first facets are rectangular.

17. An optical system, comprising:
an illumination optical unit according to claim 1; and
a projection optical unit configured to image the object field into an image field of the projection optical unit.

18. An illumination system, comprising:
an EUV light source configured to provide the illumination light; and
an illumination optical unit according to claim 1.

19. A projection exposure apparatus, comprising:
an EUV light source configured to provide the illumination light;
an illumination optical unit according to claim 1; and
a projection optical unit configured to image the object field into an image field of the projection optical unit.

20. A method of using a projection exposure apparatus comprising an illumination optical unit and a projection optical unit, the method comprising:
using the illumination optical unit to illuminate an object comprising a light-sensitive material in an object field of the projection optical unit; and
using the projection optical unit to image the illuminated object into an image field of the projection optical unit,
wherein the illumination optical unit comprises an illumination optical unit according to claim 1.
